(19) United States
(12) Patent Application Publication
(10) Pub. No.: US 2024/0117492 A1
(43) Pub. Date: Apr. 11, 2024

(54) LIQUID-SOURCE PRECURSOR DELIVERY SYSTEM APPARATUS AND METHOD OF USING SAME

(71) Applicant: ASM IP Holding B.V., Almere (NL)

(72) Inventor: Koei Aida, Tokyo (JP)

(21) Appl. No.: 18/376,524

(22) Filed: Oct. 4, 2023

Related U.S. Application Data
(60) Provisional application No. 63/414,365, filed on Oct. 7, 2022.

(51) Int. Cl. C23C 16/455; C23C 16/448

(52) U.S. Cl. CPC C23C 16/45561; C23C 16/448; C23C 16/45557

(57) ABSTRACT

Liquid delivery system apparatus and reactor systems including such apparatus are disclosed. Exemplary liquid delivery system apparatus can be used to provide desired control of a flowrate of a liquid-source precursor, while mitigating fluctuations in flowrate that might otherwise occur and while allowing for a relatively low number of fluid lines.

### CROSS-REFERENCE TO RELATED APPLICATIONS

This application claims priority to U.S. Provisional Patent Application Ser. No. 63/414,365 filed Oct. 7, 2022 titled LIQUID-SOURCE PRECURSOR DELIVERY SYSTEM APPARATUS AND METHOD OF USING SAME, the disclosure of which is hereby incorporated by reference in its entirety.

### FIELD OF INVENTION

The present disclosure generally relates to precursor delivery systems and apparatus. More particularly, the disclosure relates to methods and apparatus for delivering a liquid-source precursor to a process module.

### BACKGROUND OF THE DISCLOSURE

During the manufacture of electronic devices, thin films or layers are often deposited onto a surface of a substrate using one or more precursors. In some cases, the precursor can be a liquid at normal temperature and pressure (NTP) and can be vaporized for use in gas-phase reactions. The precursor can be delivered to a reaction chamber using a liquid delivery system.

In some cases, multiple reaction chambers can receive the precursor from a liquid delivery system. In such cases, operation of one reaction chamber coupled to the liquid delivery system can cause variation in an amount of precursor supplied to another reaction chamber coupled to the liquid delivery system. For example, vibration that arises from movement of a valve of a vaporizer associated with a reaction chamber can cause such vibration and variation of flow of the precursor to another reaction chamber.

To mitigate variation in an amount of precursor supplied to the reaction chambers, a reactor system, such as reactor system 100, illustrated in FIG. 1, can include a liquid delivery system 102, a process module system 104, and a plurality of lines 106-112, wherein each line is dedicated to a respective process module M1-M4 and is independently coupled to liquid delivery system 102. In the illustrated example, modules M1 and M2 include two vaporizers (V) and two reaction chambers (RC). Modules M3 and M4 can be similarly configured.

While reactor systems, such as reactor system 100, work for a variety of applications, using a dedicated line for each process module may be relatively expensive. Further, such systems may be difficult to implement, because a liquid delivery system 102 may have a limited number of outlet ports, which limits a number of process modules or reaction chambers that can be coupled to liquid delivery system 102.

Accordingly, improved reactor systems and liquid delivery system apparatus for providing a liquid-source precursor to a process module system are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to liquid delivery system apparatus, reactor systems including the liquid delivery system apparatus, and methods of using the same. While the ways in which various embodiments of the present disclosure address drawbacks of prior systems and methods are discussed in more detail below, in general, various embodiments of the disclosure provide liquid delivery system apparatus that mitigate effects of vibration that can result from operation of vaporizers and/or mitigate variation in an amount of precursor delivered from a liquid delivery system to a process module of a process module system and to methods of using such apparatus.

In accordance with examples of the disclosure, a liquid delivery system apparatus for providing a liquid-source precursor to a reactor includes a precursor source, a fluid line, a vaporizer, and a pressure regulator fluidly connected within the fluid line between the precursor source and a respective vaporizer. In accordance with examples of the disclosure, the precursor source includes a vessel and the liquid-source precursor therein. The fluid line includes a first fluid line end and a second fluid line end. The first fluid line end can be coupled to the vessel; the second fluid line end can be coupled to the respective vaporizer. The fluid line can include one, two, or more manifolds. Further, the fluid line can include a plurality of downstream segments and a plurality of pressure regulators, wherein each pressure regulator of the plurality of pressure regulators is coupled to a respective downstream segment. Each downstream segment can be coupled to a respective process module and/or a manifold. The liquid delivery system apparatus can include or be coupled to a controller to control operation of one or more of the pressure regulators, valves, and/or liquid delivery system as described herein.

In accordance with exemplary embodiments of the disclosure, a reactor system is provided. The reactor system can include a liquid delivery system apparatus, such as a liquid delivery system apparatus as described herein, and one or more process modules. In some cases, the reactor system includes two, three, or four or more process modules. Each process module can include one, two, three, four, or more reaction chambers. Exemplary systems can also include a controller to control one or more components of the reactor system.

In accordance with yet further examples of the disclosure, a method of providing a precursor to a reaction chamber is provided. The method can include providing a precursor source comprising a vessel and the precursor therein, flowing the precursor to a first pressure regulator, using the first pressure regulator, controlling a downstream pressure of the precursor within a fluid line, and using a first vaporizer, vaporizing the precursor. The step of flowing the precursor to a first pressure regulator can include using a carrier gas. Methods described herein can include using a plurality of pressure regulators, a plurality of vaporizers, and the like.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system including a plurality of fluid lines.

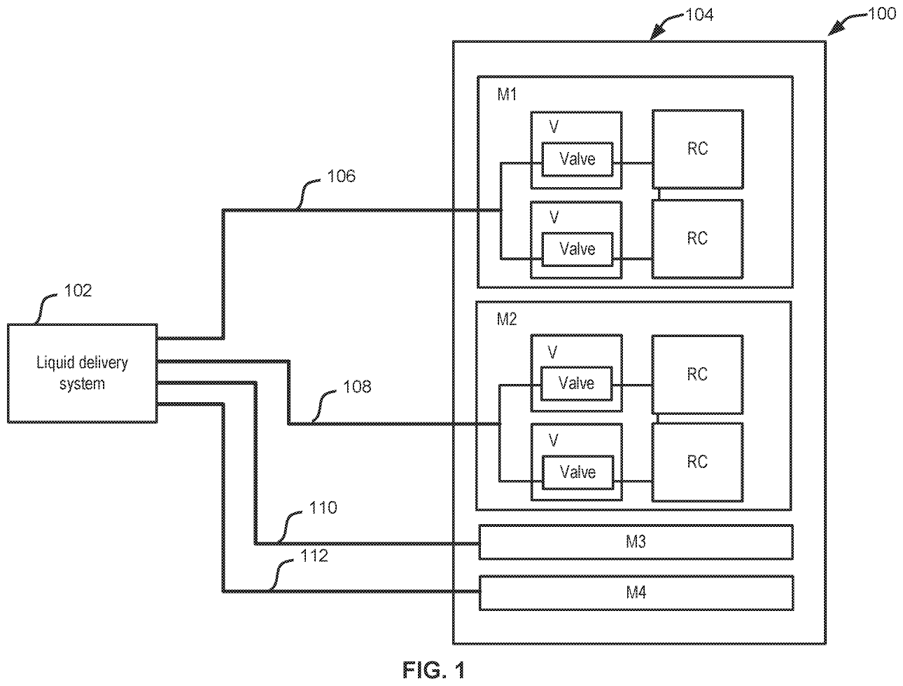

FIG. 2 illustrates a reactor system in accordance with exemplary embodiments of the disclosure.

FIG. 3 illustrates a mixing vaporizer suitable for use as a vaporizer in accordance with examples of the disclosure.

FIG. 4 illustrates a vapor controller suitable for use as a vaporizer in accordance with additional examples of the disclosure.

FIG. 5 schematically illustrates a reaction chamber in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to liquid delivery system apparatus, reactor systems including liquid delivery system apparatus, and to methods of using the same. The liquid delivery system apparatus described herein can mitigate effects, such as variation or fluctuation in precursor flowrates to a reaction chamber, which might otherwise occur during operation of the reaction system, while allowing for a relatively low number (e.g., 1 or less than a number of process modules or a number of reaction chambers coupled to the liquid delivery system) of lines coupled to the liquid delivery system. For example, exemplary liquid delivery system apparatus can mitigate deleterious effects of vibration that can occur during operation of a vaporizer associated with a process module with only one line or a numbers of lines less than a number of process modules and/or reaction chambers coupled to the liquid delivery system.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as an inert gas.

In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor. In some cases, the terms precursor and reactant can be used interchangeably. The term “inert gas” refers to a gas that does not take part in a chemical reaction to an appreciable extent. A carrier gas can be an inert gas, such as helium (He), argon (Ar), or nitrogen (N₂).

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

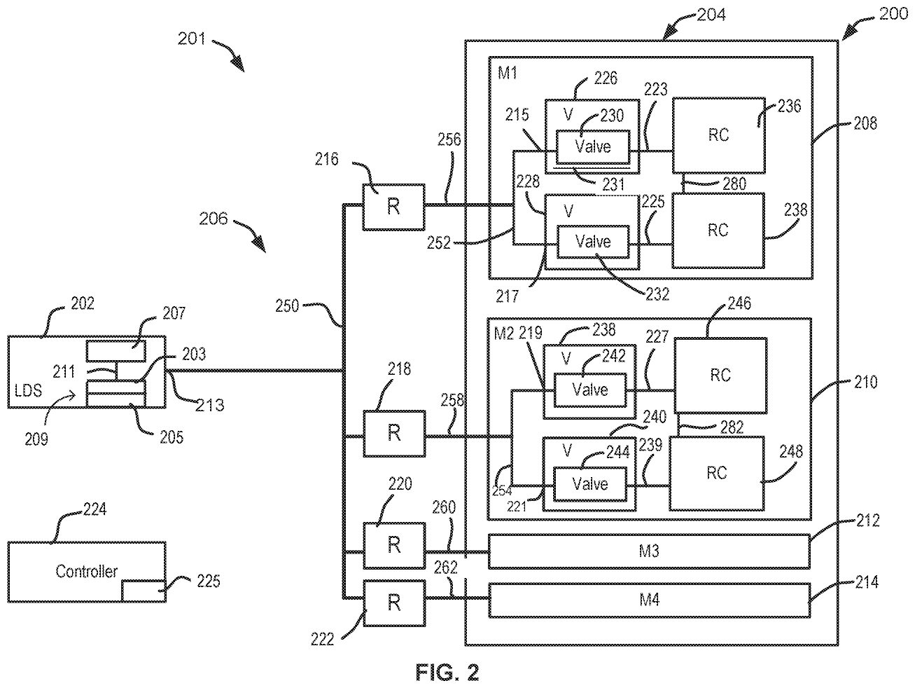

Turning again to the figures, FIG. 2 illustrates a reactor system 200 in accordance with examples of the disclosure. Reactor system 200 includes a liquid delivery system apparatus 201 and a process module system 204.

Liquid delivery system apparatus 201 is configured to provide a liquid-source precursor to process module system 204. In the illustrated example, liquid delivery system apparatus 201 includes a liquid delivery system (LDS) 202, a fluid line 206, one or more vaporizers 226, 228, 238, 240, and one or more pressure regulators 216, 218, 220, 222 within fluid line 206.

Liquid delivery system 202 is configured to supply a precursor that is a liquid at normal temperature and pressure (NTP) to vaporizers 226, 228, 238, 240. In the illustrated example, liquid delivery system 202 includes a precursor source 209 that includes a vessel 203 and a liquid-source precursor 205 therein. Vessel 203 can be formed of any suitable material, such as stainless steel, nickel alloy, or the like. The precursor can be or include, for example, a silicon and/or carbon-containing precursor. Exemplary precursors can be represented by the formula: SiₐC_{b}H_{c}O_{d}Nₑ, where a is a natural number no greater than 5, b is a natural number no less than 1 and no greater than 20, c is a natural number no less than 1 and no greater than 40, d is 0 or a natural number no greater than 10, and e is 0 or a natural number no greater than 5. The precursor can include a chain or cyclic molecule having one or more carbon atoms, one or more silicon atoms, and one or more hydrogen atoms, such as molecules represented by the formula above. By way of particular examples, the precursor can be or include tetraethyl orthosilicate (TEOS), dimethyldimethoxysilane (DMDMOS), dimethoxymethylsilane (DMOMS), octamethylcyclotetrasiloxane (OMCTS), tetramethylcyclotetrasiloxane (TMCTS), octamethoxydodecasiloxane (OMODDS), diethoxymethylsilane (DEMS), vinyltrimethylsilane (VTMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), dicyclopentyldimethoxysilane (DcPDMS), vinylmethyldimethoxysilane (VMDMOS), or the like.

In accordance with examples of the disclosure, liquid delivery system 202 also includes a gas source 207 coupled to vessel 203. Gas source 207 can include a pressurized source of one or more of, for example, nitrogen (N₂), argon (Ar) and helium (He)—i.e., one or more carrier gases. Gas source 207 can be coupled to vessel 203 via line 211. Gas source 207 can be used to provide pressurized transfer of liquid-source precursor 205 to downstream reactor system 200 components—e.g., to vaporizers 226, 228, 238, 240.

Fluid line 206 includes a first fluid line end 213 and a second fluid line end 215. First fluid line end 213 is coupled to vessel 203. Second fluid line end 215 is coupled to a vaporizer 226. As illustrated, fluid line 206 can include a single first fluid line end 213 and a plurality of second fluid line ends 215, 217, 219, 221, each second fluid line end 215, 217, 219, 221 coupled to a respective vaporizer 226, 228, 238, 240.

Fluid line 206 includes one or more (e.g., a plurality of) pressure regulators 216, 218, 220, 222, wherein each pressure regulator of the plurality of pressure regulators is connected within fluid line 206 between first fluid line end 213 and the second fluid line end(s) 215, 217, 219, 221 or between vessel 203 and respective process modules 208, 210, 212, 214. Additionally or alternatively, each pressure regulator may be disposed in a second fluid line.

Each pressure regulator 216, 218, 220, 222 can be configured to control a pressure in fluid line 206 downstream of the respective pressure regulator 216, 218, 220, 222. For example, each pressure regulator 216, 218, 220, 222 can be configured to control a pressure within fluid line 206 between the respective pressure regulator and the respective second end 215, 217, 219, 221 or respective vaporizer 226, 228, 238, 240. By way of examples, an upstream pressure in fluid line 206 can be 0.2-1 MPa and a downstream, controlled pressure can be 0.1-0.5 MPa.

In the illustrated example, fluid line 206 includes a plurality of downstream segments 256, 258, 260, 262, which are downstream of the respective pressure regulator 216, 218, 220, 222 and upstream of the respective vaporizers 226, 228, 238, 240. In the illustrated example, each pressure regulator 216, 218, 220, 222 of the plurality of pressure regulators is coupled to a respective downstream segment 256, 258, 260, 262, which, in turn, are coupled to a respective vaporizer 226, 228, 238, 240.

In accordance with the illustrated example, fluid line 206 can include a first manifold 250 and/or one or more second manifolds 252, 254. First manifold 250 is in fluid line 206 and interposed between first fluid line end 213 and pressure regulators 216, 218, 220, 222. Second manifold(s) 252, 254 are in fluid line 206 and interposed between respective pressure regulators 216, 218, 220, 222 and respective second fluid line ends 215, 217, 219, 221.

Process module system 204 can include one or more process modules M1-M4, 208-214. For example, process module system 204 can include two, three, four, or more process modules 208-214. In the illustrated example, process module system 204 includes four process modules 208-214.

Each process module 208-214 can include one, two, or more reaction chambers (RC) 236, 238, 246, 248 and one or more vaporizers 226, 228, 238, 240. Process modules 208-214 can suitably include other components typically included in gas-phase process modules.

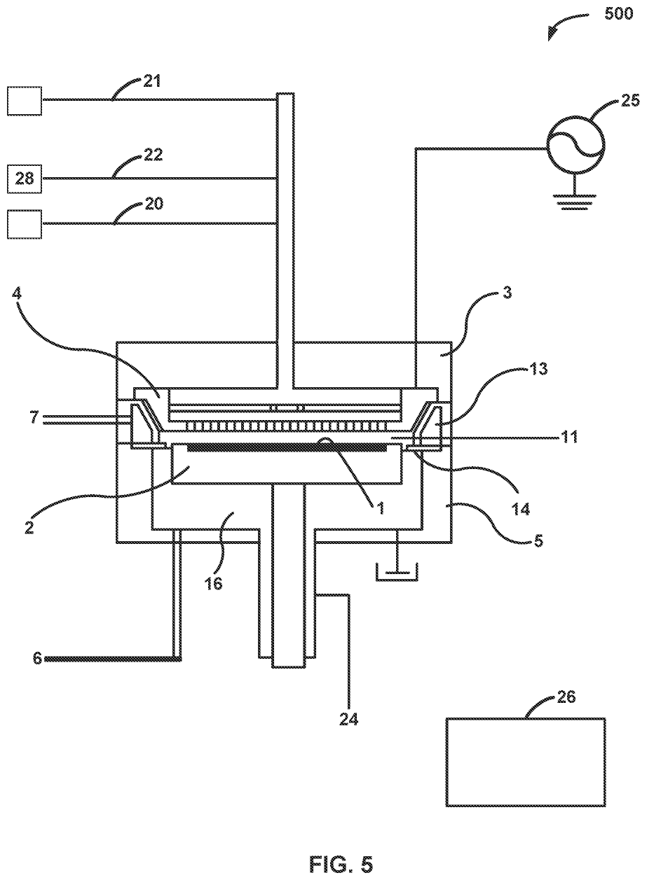

Reaction chamber 236, 238, 246, 248 can be or include any suitable reaction chamber. By way of example, FIG. 5 illustrates an exemplary reaction chamber 500 (e.g., suitable for use as reaction chamber 236, 238, 246 and/or 248) in greater detail. Reaction chamber 500 can be used to perform, for example, plasma-enhanced processes, such as plasma-enhanced chemical vapor deposition, plasma-enhanced atomic layer deposition, or a hybrid thereof, wherein one or more of a reactant, a precursor, and a plasma power are pulsed during a deposition cycle.

In the illustrated example, reaction chamber 500 includes a pair of electrically conductive flat-plate electrodes 4, 2 in parallel and facing each other in the interior 11 (reaction zone) of a chamber 3. A plasma can be excited within chamber 3 by applying, for example, HRF power (e.g., 13.56 MHz or 27 MHz) from power source 25 to one electrode (e.g., electrode 4) and electrically grounding the other electrode (e.g., electrode 2). A temperature controller can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into chamber 3 using one or more of a gas line 20, a gas line 21, and a gas line 22, respectively, and through the shower plate 4. Although illustrated with three gas lines, a reaction chamber can include any suitable number of gas lines. Gas line 20 can be coupled to a vaporizer, such as a vaporizer described herein, and gas line 22 can be coupled to another (e.g., reactant) gas source 28.

In chamber 3, a circular duct 13 with an exhaust line 7 is provided, through which gas in the interior 11 of the chamber 3 can be exhausted. Additionally, a transfer region 5, disposed below the chamber 3, is provided with a seal gas line 24 to introduce seal gas into the interior 11 of the chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6.

Reaction chamber 500 also includes one or more controller(s) 26 programmed or otherwise configured to cause one or more method (e.g., deposition) steps to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a precursor and an inert gas. Controller 26 can be a standalone controller or can form part of a controller 224, illustrated in FIG. 2 and described below.

With reference to FIGS. 2 and 5, in some embodiments, a dual chamber reactor (two sections or compartments for processing wafers disposed close to each other) can be used, wherein a reactant gas and a noble gas can be supplied through a shared line (e.g., line 280, 282, illustrated in FIG. 2), whereas a precursor gas is supplied through unshared lines (e.g., lines 223, 225, 227, 229).

With reference to FIGS. 2, 3, and 4, exemplary vaporizers 226, 228, 238, and 240 are illustrated. Vaporizers 226, 228, 238, and 240 are generally configured to heat the liquid-source precursor to form a vaporized precursor. As illustrated in FIG. 2, one or more vaporizers 226, 228, 238, and 240 can include a heater 231 to heat the liquid-source precursor and one or more control valves 230, 232, 242, 244 to control a flowrate of the precursor (e.g., by weight or volume of the precursor/time) to the respective reaction chamber 236, 238, 246, 248. For example, vaporizers 226, 228, 238, and 240 can be configured to control a volumetric flowrate of greater than zero or greater than 1 and less than 20000 sccm. Although only vaporizer 226 is illustrated with heater 231, other vaporizers described herein can also include a heater. As described in more detail below, control valves 230, 232, 242, 244 can be used to control a mass or volume flowrate of a precursor to the respective reaction chambers 236, 238, 246, 248.

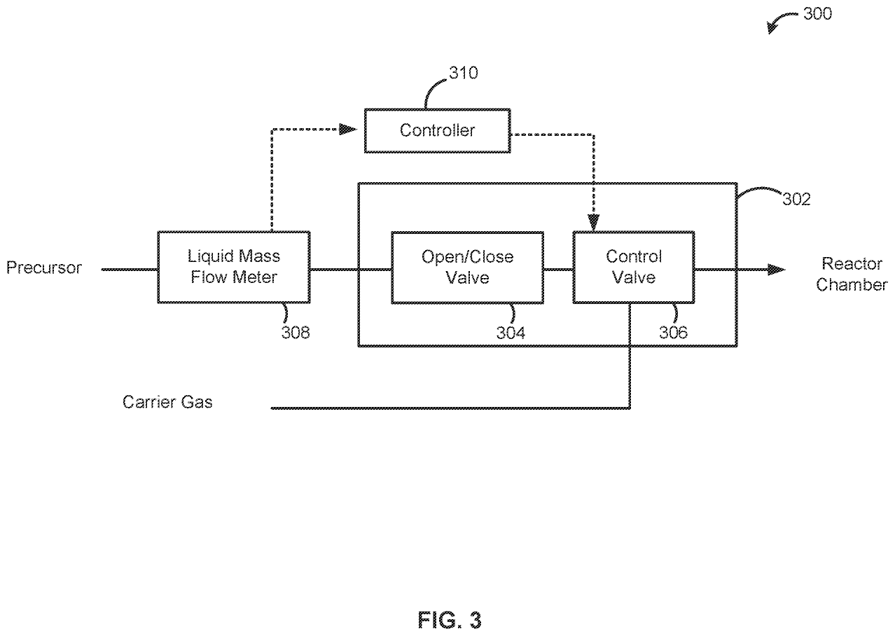

FIG. 3 illustrates an exemplary flow control system 300 including a liquid mass flow meter 308, mixing vaporizer (MV) 302, and a controller 310. Flow control system 300 is suitable for use as one or more of vaporizers 226, 228, 238, and 240, illustrated in FIG. 2. Flow control system 300 can be used to control a mass flowrate (e.g., in grams per minute) by controlling the liquid flowrate of the precursor. For example, the controlled flowrate can be between about 50 mg/min and about 50 g/min.

In the illustrated example, mixing vaporizer 302 includes an open/close valve 304 and a control valve 306. Open/close valve 304 can be or include any suitable valve, such as a pneumatic valve, air operation valve. Control valve 306 can include any suitable valve, such as a piezo valve. As illustrated, control valve 306 can receive vaporized precursor and a carrier gas, such as a carrier gas noted herein.

Liquid mass flow meter 308 can include any suitable liquid mass flow meter. In accordance with examples of the disclosure, liquid mass flow meter 308 generates an output signal indicative of a liquid mass flowrate.

Controller 310 can be configured to control a flowrate of the vaporized precursor. By way of example, controller 310 can receive the output signal indicative of a liquid mass flowrate from liquid mass flow meter 308 and, in turn, generate a control signal and send the control signal to control valve 306 to control the flowrate of the vaporized precursor to the respective reaction chamber. Controller 310 can be a standalone controller or form part of controller 224, described below.

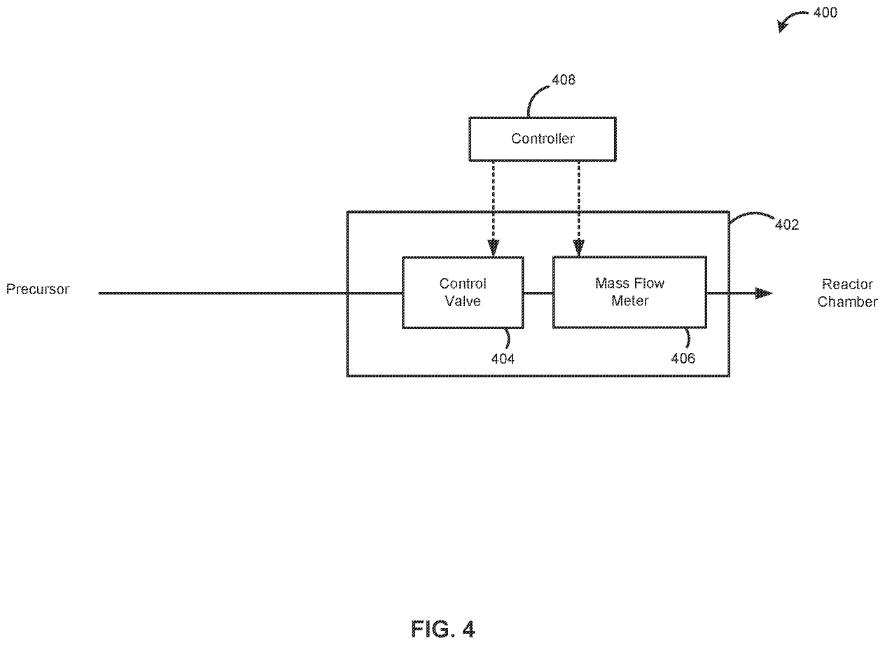

FIG. 4 illustrates an exemplary flow control system 400 for use as one or more of vaporizers 226, 228, 238, and 240 in accordance with further examples of the disclosure. In the illustrated example, flow control system 400 includes a vapor controller 402 and a controller 408. Flow control system 400 can vaporize a precursor, without need for a carrier gas.

Vapor controller 402 includes a control valve 404 and a mass flow meter 406. Control valve 404 can include any suitable control valve, such as the control valves described above. Mass flow meter 406 can include any suitable mass flow meter.

Controller 408 can be configured to provide a control signal to mass flow meter 406 and to control valve 404 to control a volumetric flowrate of vaporized precursor to a respective reaction chamber. By way of example, a flowrate can be controlled between about 5 and about 20000 sccm.

Returning now to FIG. 2, controller 224 can be used to control one or more components of reactor system 200. Controller 224 can be coupled with the various power sources, heating systems, pumps, robotics and gas flow controllers, or valves of reactor system 200. By way of example, controller 224 can be configured to control pressure regulators 216, 218, 220, 222, as well as other reactor system 200 components.

Controller 224 can include electronic circuitry and software 225 to control pressure regulators 216, 218, 220, 222.

Controller 224 can include control software to electrically or pneumatically control valves to control flow of precursors, reactants, and/or purge gases into and out of the reaction chambers 236, 238, 246, 248. Controller 224 can include modules, such as a software or hardware component, e.g., a FPGA or ASIC, which perform certain tasks. A module can advantageously be configured to reside on the addressable storage medium of the control system and be configured to execute one or more processes.

In accordance with yet further examples of the disclosure, a method of providing a precursor to a reaction chamber is provided. An exemplary method includes the steps of providing a precursor source comprising a vessel and the precursor therein, using a carrier gas, flowing the precursor to a first pressure regulator, using the first pressure regulator, controlling a downstream pressure of the precursor within a fluid line, and using a first vaporizer, vaporizing the precursor and controlling a flowrate of the vaporized precursor to the reaction chamber. The method can further include, using a second vaporizer, controlling a flowrate of the precursor in vapor form to a second reaction chamber. Exemplary methods can further comprise using a third, fourth, etc. vaporizer to similarly control a flow of vaporized precursor from the precursor source to a respective reaction chamber. One or more vaporizers (e.g., the first vaporizer and the second vaporizer) can be coupled to a manifold within the fluid line. The method can further include a step of pressurizing the precursor within the vessel—e.g., using a carrier gas as described above.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

1. A liquid delivery system apparatus for providing a liquid-source precursor to a reactor, the liquid delivery system apparatus comprising:
a precursor source comprising a vessel and the liquid-source precursor therein;
a fluid line comprising a first fluid line end and a second fluid line end, the first fluid line end coupled to the vessel;
a vaporizer coupled to the second fluid line end; and
a pressure regulator fluidly connected within the fluid line between the first fluid line end and the second fluid line end, the pressure regulator configured to control a pressure in the fluid line downstream of the pressure regulator.

2. The liquid delivery system apparatus of claim 1, wherein the vaporizer comprises a control valve to control a downstream flowrate of a vaporized precursor.

3. The liquid delivery system apparatus of claim 2, wherein the flowrate is less than 20000 sccm.

4. The liquid delivery system apparatus of claim 1, further comprising a gas source coupled to the vessel.

5. The liquid delivery system apparatus of claim 4, wherein the gas source comprises one or more of nitrogen (N₂), argon (Ar) and helium (He).

6. The liquid delivery system apparatus of claim 1,
wherein the fluid line comprises a plurality of downstream segments,
wherein the liquid delivery system apparatus comprises a plurality of pressure regulators, including the pressure regulator, and
wherein each pressure regulator of the plurality of pressure regulators is coupled to a respective downstream segment.

7. The liquid delivery system apparatus of claim 1, further comprising a first manifold in the fluid line and interposed between the first fluid line end and the pressure regulator.

8. The liquid delivery system apparatus of claim 1, further comprising a second manifold in the fluid line and interposed between the pressure regulator and the second fluid line end.

9. A reactor system comprising:
a process module comprising one or more reaction chambers and one or more vaporizers; and
a liquid delivery system apparatus, the liquid delivery system apparatus comprising:
a precursor source comprising a vessel and a liquid-source precursor therein;
a fluid line comprising a first fluid line end and a second fluid line end, the first fluid line end coupled to the vessel and the second fluid line end coupled to a vaporizer of the one or more vaporizers; and
a pressure regulator connected within the fluid line between the first fluid line end and the second fluid line end, the pressure regulator configured to control a pressure in the fluid line downstream of the pressure regulator.

10. The reactor system of claim 9, wherein the reactor system comprises two or more reaction chambers.

11. The reactor system of claim 9, comprising two or more process modules.

12. The reactor system of claim 11, comprising a plurality of pressure regulators, wherein each pressure regulator of the plurality of pressure regulators is connected within the fluid line between the vessel and the respective process module of the two or more process modules.

13. The reactor system of claim 9, further comprising a first manifold within the fluid line and between the first fluid line end and the pressure regulator.

14. The reactor system of any of claim 9, further comprising a second manifold within the fluid line and between the pressure regulator and the second fluid line end.

15. The reactor system of any of claim 9, wherein the vaporizer comprises a control valve.

16. A method of providing a precursor to a reaction chamber, the method comprising the steps of:
providing a precursor source comprising a vessel and the precursor therein;
using a carrier gas, flowing the precursor to a first pressure regulator;
using the first pressure regulator, controlling a downstream pressure of the precursor within a fluid line; and
using a first vaporizer, vaporizing the precursor.

17. The method of claim 16, further comprising, using a second vaporizer, controlling a flowrate of the precursor in vapor form to a second reaction chamber.

18. The method of claim 17, wherein the first vaporizer and the second vaporizer are coupled to a manifold within the fluid line.

19. The method of claim 16, further comprising a step of pressurizing the precursor within the vessel.

20. The method of any of claim 16, further comprising controlling a flowrate of vaporized precursor from the first vaporizer to the first reaction chamber.
